(19) United States
(12) Patent Application Publication
(10) Pub. No.: US 2007/0126054 A1
(43) Pub. Date: Jun. 7, 2007

(54) Nonvolatile memory devices having insulating spacer and manufacturing method thereof

(75) Inventor: Jin Hyo Jung, Bucheon-si (KR)

Correspondence Address: PILLSBURY WINTHROP SHAW PITTMAN, LLP, P.O. BOX 10500, MCLEAN, VA, 22102, US

(73) Assignee: DongbuAnam Semiconductor Inc., Seoul (KR)

(21) Appl. No.: 11/315,295

(22) Filed: Dec. 23, 2005

(30) Foreign Application Priority Data
Dec. 1, 2005 (KR) 10-2004-0116598

(51) Int. Cl. H01L 29/792

(52) U.S. Cl. 257/324

(57) ABSTRACT

A nonvolatile memory device that effectively prevents the occurrence of the hump phenomenon as well as a manufacturing method for fabricating the same, is presented. In one embodiment, the nonvolatile memory device includes an insulating spacer formed at interface between the active region and isolation layer, and a charge trapping dielectric layer that is formed in the active region between the neighboring two insulating spacers. The device also includes a gate electrode layer formed on the charge trapping dielectric layer and a source and drain formed in the active region at both sides of the gate electrode layer.

### BACKGROUND OF THE INVENTION

1. Related Application and Priority Information

This application claims priority to and the benefit of Korean Patent Application No. 10-2005-0116598 filed in the Korean Intellectual Property Office on Dec. 1, 2005, the entire contents of which are incorporated herein by reference.

2. Field of the Invention

The present invention relates to nonvolatile memory technologies, and more specifically, to SONOS structured nonvolatile memory devices having insulating spacers formed at the interfaces between isolation layers and active regions.

3. Description of the Related Art

Most of the nonvolatile memories are floating gate devices like flash memory devices. As the single type flash memory device cannot satisfy requirements for high-integration, a multi bit cell, which has at least two gate structures in a single cell, has been developed. For embodying the multi bit cell, silicon-oxide-nitride-oxide-semiconductor (SONOS) structure nonvolatile memory has been used.

SONOS memory was introduced in Chan et al, IEEE Electron Device Letters, Vol. 8, No. 3, p. 93, 1987, and the SONOS memory cells are constructed having a charge trapping non-conducting dielectric layer, typically a silicon nitride layer, sandwiched between two insulating layers, typically silicon dioxide layers. A conducting gate layer is placed over the upper silicon dioxide layer. Since the electrical charge is trapped locally near the drain, this structure can be described as a two-transistor cell, or two-bits cell. If multi-bit is used, then four or more bits per cell can be accomplished. Multi-bit cells enable SONOS memory devices to have advantage over others in facilitating the continuing trend increasing the amount of information held/processed on an integrated circuit chip. The SONOS memory has been considered as a replacement for the floating gate nonvolatile memory and has various advantages of good scalability, simplicity of cell structure and process, high-density, and low-voltage operation. Further, SONOS nonvolatile memory transistor has a fast programming time, good retention, and high endurance, and the programming voltage of SONOS memory can be scaled.

One of drawbacks of SONOS memory is a hump phenomenon that occurs because a tunnel oxide fails to have uniform thickness in an active region where SONOS memory cells are to be constructed.

FIGS. 1A to 1C are images showing hump phenomenon of the conventional SONOS memory device. As shown in FIGS. 1A to 1C, the conventional SONOS memory cell is formed in an active region 5 separated by an isolation layer 5, and has SONOS structure of a tunnel oxide layer 12, a dielectric layer 14, a block oxide layer 16, and gate polysilicon layer 18. Here, the isolation layer 5 has shallow trench isolation (STI) structure and the dielectric layer 14 is a silicon nitride layer in which electrical charges are trapped.

As denoted by dotted rectangular 1B and 1C of FIG. 1A and circles B and C of FIGS. 1B and 1C, the tunnel oxide 12 has thicker portion (greater than about 2 times) near the corner rounding of the STI isolation layer 5 than the tunnel oxide 12 in the active region 5. The reason for the thicker portion of tunnel oxide is that stress is concentrated at the corner rounding regions (i.e., the interfaces between the isolation layer and active region) and the crystal direction (e.g., [111] direction) of the silicon substrate.

When the tunnel oxide 12 grows thicker locally, a parasitic transistor is generated in the location as shown in FIG. 2. That is to say, a parasitic transistor 20 is formed at the corner rounding regions due to the thicker tunnel oxide in addition to the SONOS transistor 25 that consists of the gate polysilicon 18, source 22 and drain 24 in the active region 8.

FIG. 3 is an equivalent circuit diagram of the conventional SONOS memory cell layout of FIG. 2. Referring to FIG. 3, two parasitic transistors 20 are connected in parallel to the SONOS transistor 25. The parasitic transistor 20 prevents the normal erase and program operations of the SONOS transistor 25. One of the reasons is that the parasitic transistor 20 has a constant threshold voltage regardless of the transistor operations (erase or program operation) differently from the SONOS transistor 25. Thus, hump phenomenon occurs, in particular during the program operation of the SONOS transistor 25.

When the SONOS transistor 25 is in erase operation mode, the SONOS transistor 25 in which the trapped charges are easily removed or erased, experiences the lowering of threshold voltage, while the parasitic transistors 20 in which the trapped charges are not removed have the threshold voltage unchanged. Therefore, during the data read operation from the SONOS transistor 25, the main current source is the SONOS transistor 25 and thus leakage current from the parasitic transistors 20 is ignorable. Thus, as shown in FIG. 4, the hump phenomenon is rarely observed in the erase operation.

In contrast, when the SONOS transistor 25 is in a program operation mode, the SONOS transistor 25 in which electrical charges are easily trapped experiences the rise of threshold voltage, while the parasitic transistors 20 in which electrical charges are not trapped have the threshold voltage unchanged. In other words, the threshold voltage of parasitic transistor 20 is lower than that of the SONOS transistor 25. Therefore, the parasitic transistors 20 turn-on earlier than the SONOS transistor 25 and act as a main current source in data read operation from the SONOS transistor 25. Thus the leakage current from the parasitic transistors 20 is no longer ignorable and the hump phenomenon becomes worsen as denoted by circle ‘D’ in FIG. 5.

The hump phenomenon induces failure of data read operation in the SONOS transistor 25 and makes widen the threshold voltage distribution in the program operation. Further, the leakage current and soft fail are increased due to the parasitic transistors 20 of the programmed SONOS cells. Measures are thus need to prevent the hump phenomenon.

### SUMMARY OF THE INVENTION

Principles of the present invention, as embodied and broadly described herein, are directed to providing nonvolatile memory devices that effectively prevent the occurrence of the hump phenomenon and a manufacturing method for fabricating the same. In one embodiment, the present invention may be directed to a nonvolatile memory device which is formed in an active region separated by isolation layers, and comprises: (a) an insulating spacer formed at interface between the active region and isolation layer; (b) a charge trapping dielectric layer formed in the active region between the neighboring two insulating spacers; (c) a gate electrode layer formed on the charge trapping dielectric layer; and (d) source and drain formed in the active region at both sides of the gate electrode layer.

In another embodiment, the present invention may be directed to a method of fabricating a nonvolatile memory device, comprising: (a) forming isolation layers and an active region electrically separated by the isolation layers on a semiconductor substrate; (b) depositing insulating material on the overall surface of the substrate; (c) blanket-etching the deposited insulating material to form an insulating spacer at an interface between the isolation layer and active region; (d) forming a charge trapping dielectric layer in active region between neighboring two insulating spacers; and (e) forming a gate electrode on the charge trapping dielectric layer.

### BRIEF DESCRIPTION OF DRAWINGS

The accompanying drawings, which are incorporated in and constitute a part of this Specification, depict corresponding embodiments of the invention, by way of example only, and it should be appreciated that corresponding reference symbols indicate corresponding parts. In the drawings:

FIGS. 1A to 1C are images showing the hump phenomenon occurred in the conventional SONOS memory device;

FIG. 2 is a layout of the conventional SONOS memory cell;

FIG. 3 is an equivalent circuit diagram of SONOS memory cell of FIG. 2;

FIG. 4 is a graph showing the variation of read current when the conventional SONOS memory device is in an erase operation;

FIG. 5 is a graph showing the variation of read current when the conventional SONOS memory device is in a program operation; and

FIGS. 6 to 12 are cross-sectional views for illustrating the structure and fabrication method of nonvolatile memory device according to the present invention.

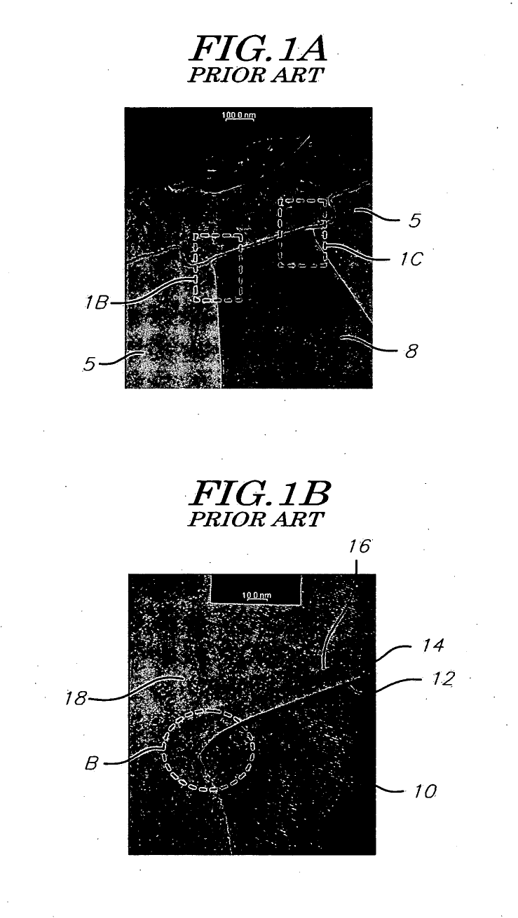

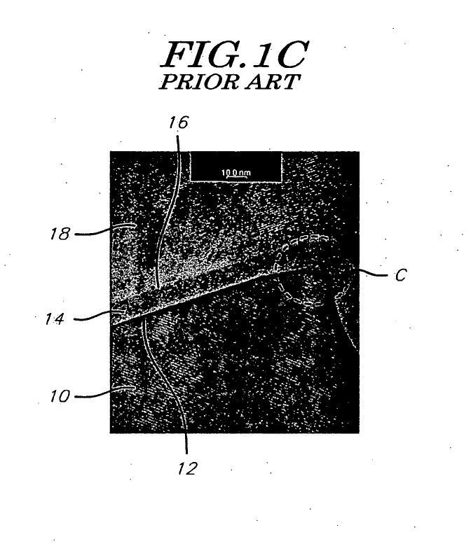

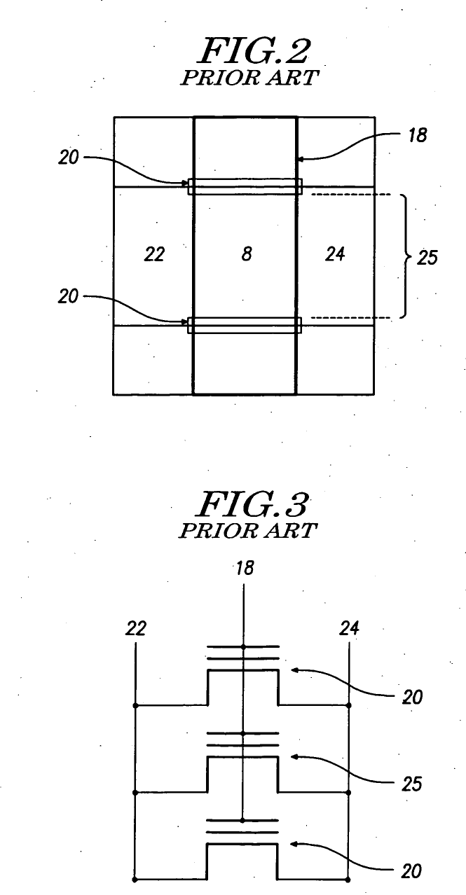

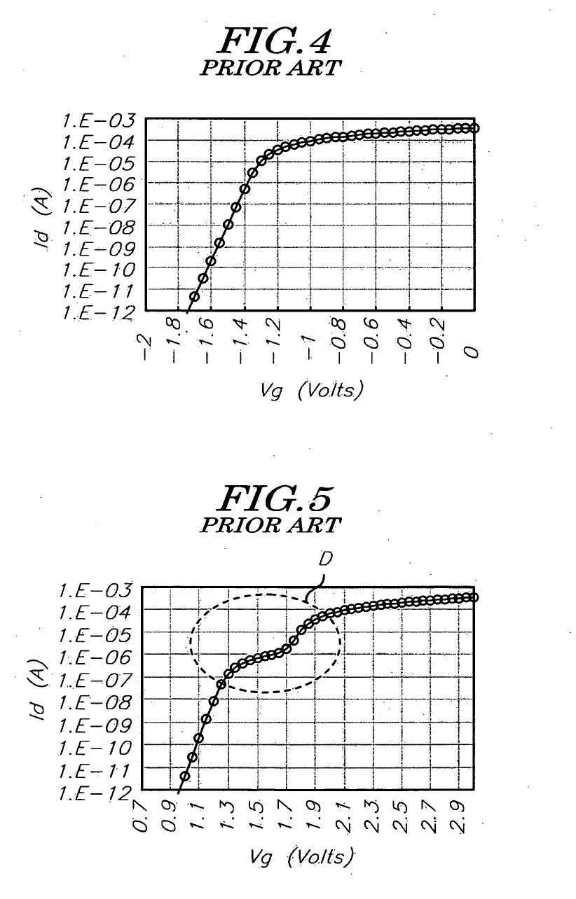

### DETAILED DESCRIPTION OF EMBODIMENTS OF THE INVENTION

Hereinafter, preferred embodiments of the present invention will be described with reference to the accompanying drawings.

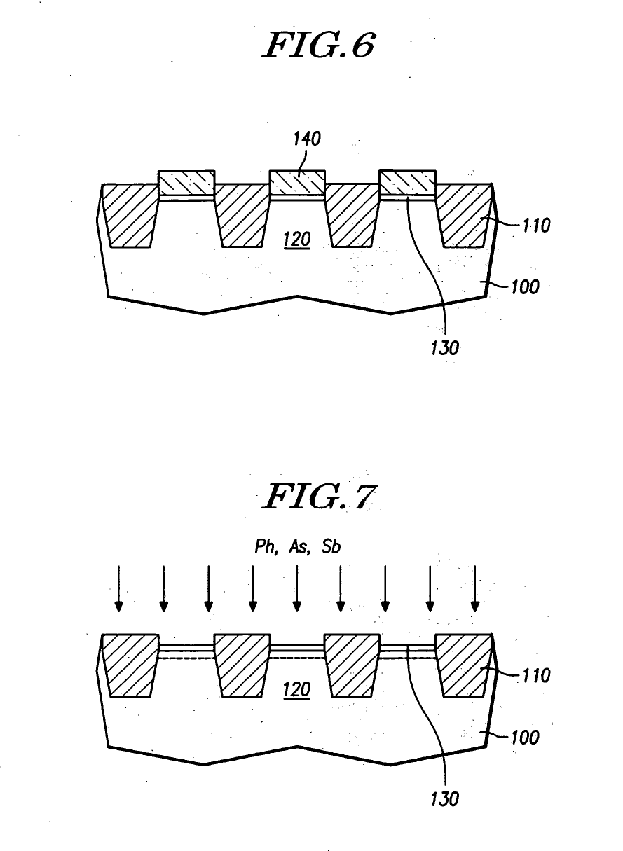

With references to FIGS. 6 to 12, a volatile memory device according to the present invention will be explained in terms of its structure and fabrication method. Referring to FIG. 6, a pad oxide layer 130 and a nitride layer 140 is formed on a semiconductor substrate 100 and isolation layers 110 are formed by a photolithographic process. In this embodiment, the isolation layers 110 have shallow trench isolation (STI) structure, and the substrate regions between the isolation layers 110 are called active regions 120 where SONOS transistors are to be formed. The STI isolation layers 110 may be formed by etching by a predetermined depth the substrate, using the nitride layer 140 as a mask to form trenches, filling the trenches with dielectric material, and planarizing the surface of substrate by e.g., chemical mechanical polishing (CMP) process.

Referring to FIG. 7, the nitride layer 140 is removed and dopants such as Ph, As or Sb are ion-implanted into the substrate 100. This ion implantation is to control the threshold voltage of SONOS memory transistors or cells.

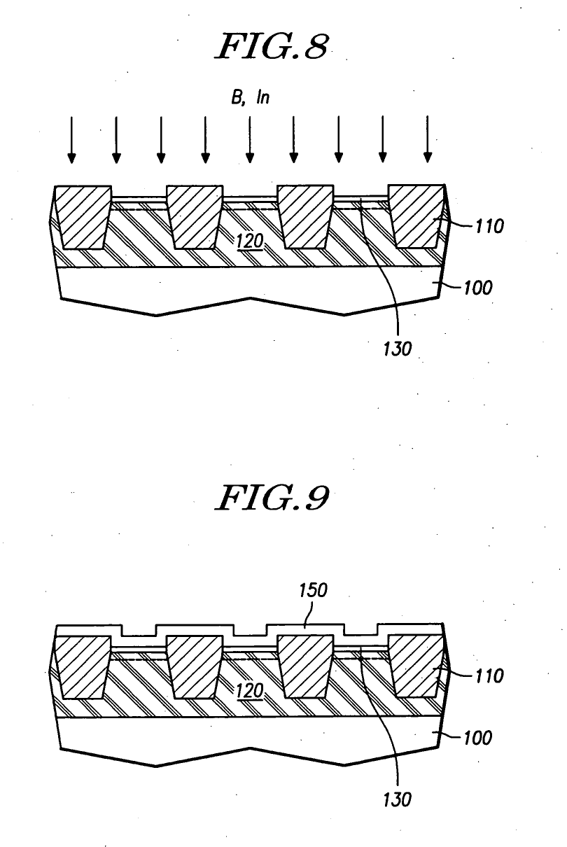

Referring to FIG. 8, dopants such as B or In are ion-implanted into the substrate where the pad oxide layer 130 exists to form N-type well or P-type well.

Referring to FIG. 9, an insulating layer 150 is deposited on the overall surface of the substrate 100. The insulating layer 150 made of e.g., by TEOS (tetraethylorthosilicate), PSG (Phosphosilicate Glass) or BPS G (Boro-PSG) may be formed by chemical vapor deposition (CVD) or spin-on technology.

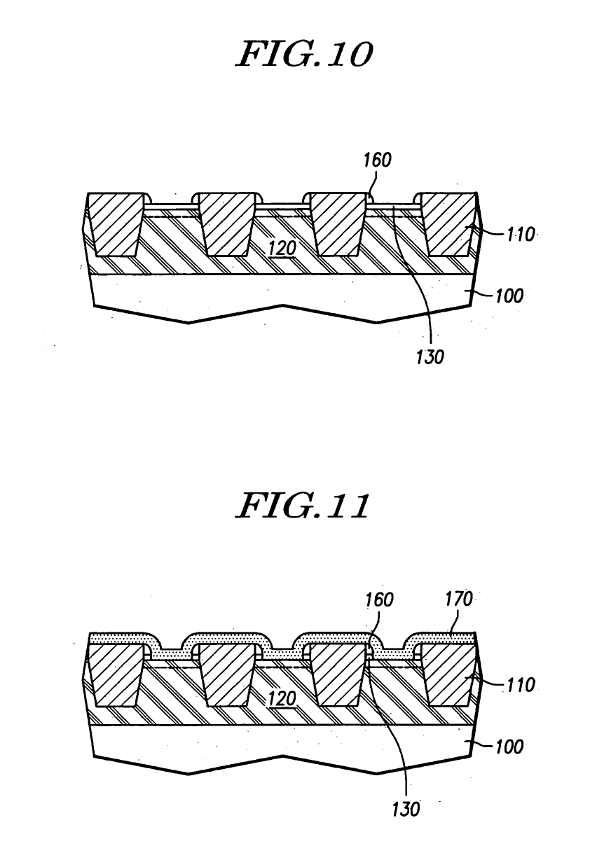

Referring to FIG. 10, insulating spacers 160 are formed at the interfaces between the STI isolation layers 110 and the active regions 120 by performing anistrophic blanket etch of the insulating layer 150. In the etching for the formation of the insulating spacers 160, a plasma etch or reactive ion etch (RIE) may be employed.

Referring to FIG. 11, the pad oxide 130 placed between the insulating spacers 160 is removed and an ONO structure 170 is formed. The ONO structure 170, which may be formed by stacking lower silicon oxide layer, silicon nitride layer and upper silicon oxide layer in this order, provides the charge trapping dielectric layer for the SONOS memory cell. In an embodiment of the present invention, the stacked three layer of the ONO structure may be replaced by oxide and nitride bilayer dielectric, oxide/titanium oxide bilayer dielectric (SiO₂ and Ti₂O₅), or silicon oxide/titanium oxide/silicon oxide trilayer dielectric. The ONO structure may be obtained by e.g., low pressure chemical vapor deposition (LPCVD).

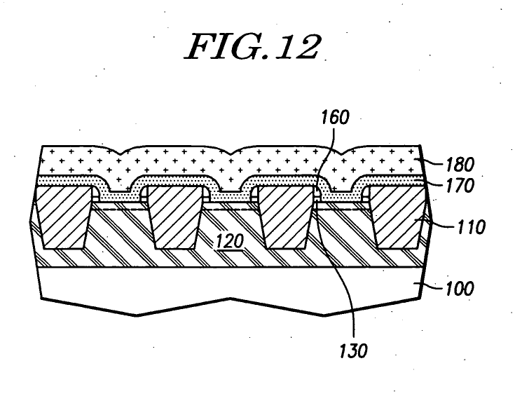

Referring to FIG. 12, a polysilicon 180 is deposited on the surface of substrate on which the ONO structure 170 is formed. Though not specifically shown in the figures, the polysilicon 180 may be patterned to form a gate electrode. For the gate electrode, doped polysilicon or doped amorphous silicon may be used.

As understandable from the cross-sectional view of FIG. 12, the nonvolatile memory device of the present invention is formed in the active region 120 separated by isolation layers, and comprises the insulating spacer 160 formed at the interface between the isolation layer and the active region, the charge trapping dielectric layer 170 formed in the active region between neighboring two insulating spacers, and a gate electrode layer 180 formed on the charge trapping dielectric layer 170. Though not explicitly depicted in FIG. 12, artisans of ordinary skill would easily understand that source and drain are formed at both sides of the gate electrode layer from FIG. 12.

Because the nonvolatile memory device according to the present invention has the insulating spacers 160 formed at the interfaces between the STI isolation layer 110 and active regions 120, the parasitic transistors that may be formed at the corner rounding regions of the STI isolation structure 110 can be completely prevented. That is to say, in the present invention, the tunnel oxide does not grow further at the corner rounding regions of the isolation layer to become thicker, and therefore the hump phenomenon in nonvolatile memory devices can be avoided.

Further, the present invention does not require multiple processing steps to be added and entail an increase of manufacturing cost, since the hump phenomenon can be prevented by adding simple processing steps such as a deposition of insulating material and blanket etch of the deposited insulating material.

While the invention has been shown and described with reference to certain preferred embodiments thereof, it will be understood by those skilled in the art that various changes in form and details may be made therein without departing from the spirit and scope of the invention as defined by the appended claims. For instance, although the embodiments disclosed above are explained with reference to the SONOS structure, the present invention can be applied to various nonvolatile memory structures such as NOR-type and NAND-type memories, and ROM (Read Only Memory), PROM (Programmable Read Only Memory), EPROM (Erasable Programmable Read Only Memory), and EEPROM (Electrically Erasable Programmable Read Only Memory).

What is claimed is:

1. A nonvolatile memory device formed in an active region separated by isolation layers, comprising:
an insulating spacer formed at interface between the active region and isolation layer;
a charge trapping dielectric layer formed in the active region between the neighboring two insulating spacers;
a gate electrode layer formed on the charge trapping dielectric layer; and
source and drain formed in the active region at both sides of the gate electrode layer.

2. The nonvolatile memory device of claim 1, wherein the insulating spacer is formed by depositing an insulating material on a semiconductor substrate, and blanket-etching the deposited insulating material.

3. The nonvolatile memory device of claim 2, wherein the insulating material includes silicon oxide, silicon nitride, TEOS (tetraethylorthosilicate), PSG (Phosphosilicate Glass) and BPSG (Boro-PSG), the blanket etching includes a plasma etching and reactive ion etching.

4. The nonvolatile memory device of claim 1, wherein the charge trapping dielectric layer includes lower silicon oxide/silicon nitride/upper silicon oxide trilayer dielectric structure, oxide/nitride bilayer dielectric structure, oxide/titanium oxide bilayer dielectric (SiO₂ and Ti₂O₅) structure, and silicon oxide/titanium oxide/silicon oxide trilayer dielectric structure.

5. A method for fabricating nonvolatile memory device, comprising:
forming isolation layers and an active region electrically separated by the isolation layers on a semiconductor substrate;
depositing insulating material on overall surface of the substrate;
blanket-etching the deposited insulating material to form an insulating spacer at an interface between the isolation layer and active region;
forming a charge trapping dielectric layer in active region between neighboring insulating spacers; and
forming a gate electrode on the charge trapping dielectric layer.

6. The method of claim 5, wherein the formation of the isolation layers and active region comprises:
depositing a pad oxide on the substrate;
depositing a nitride on the pad oxide;
patterning the pad oxide and nitride;
etching the substrate with using the patterned nitride as a mask to form the isolation layer;
removing the patterned nitride;
first ion-implanting first dopants into the substrate for controlling a threshold voltage of the non volatile memory device; and
second ion-implanting second dopants into the substrate to form a well.

7. The method of claim 5, wherein the insulating material includes silicon oxide, silicon nitride, TEOS (tetraethylorthosilicate), PSG (Phosphosilicate Glass) and BPSG (Boro-PSG), the blanket etching includes a plasma etching and reactive ion etching.

8. The method of claim 5, wherein the charge trapping dielectric layer includes lower silicon oxide/silicon nitride/upper silicon oxide trilayer dielectric structure, oxide/nitride bilayer dielectric structure, oxide/titanium oxide bilayer dielectric (SiO₂ and Ti₂O₅) structure, and silicon oxide/titanium oxide/silicon oxide trilayer dielectric structure.

9. The method of claim 5, wherein the gate electrode is formed by depositing doped polysilicon or doped amorphous silicon on the semiconductor substrate and patterning the deposited material.

10. The method of claim 5, wherein the depositing of the insulating material employs chemical vapor deposition or spin-on technology.
